(19) United States
(12) Patent Application Publication
(10) Pub. No.: US 2009/0195280 A1
(43) Pub. Date: Aug. 6, 2009

(54) INTEGRATED CIRCUIT HAVING A MEMORY WITH A PLURALITY OF STORAGE CELLS OF SYNCHRONOUS DESIGN AND CONNECTED TO CLOCK GATING UNITS

(76) Inventors: Peer Schlegel, Chemnitz (DE); Matthias Baer, Hohenstein-Ernstthal (DE); Sreenivasa Chalamala, Dresden (DE); Thomas Otto, Chemnitz (DE)

Correspondence Address: WILLIAMS, MORGAN & AMERSON, 10333 RICHMOND, SUITE 1100, HOUSTON, TX, 77042, US

(21) Appl. No.: 12/255,366

(22) Filed: Oct. 21, 2008

(30) Foreign Application Priority Data
Jan. 31, 2008 (GB) 10 2008 007 004.1

(51) Int. Cl. H03L 7/00

(52) U.S. Cl. 327/162

(57) ABSTRACT

In a memory area having portions of predictable access frequency, such as in a memory area of a real time clock unit, a synchronous design may be implemented by associating storage cells of identical access frequency with a clock gating mechanism, thereby reducing power consumption. Hence, the synchronous design of the real time clock unit may provide reduced implementation effort and enhanced verification capability.

### BACKGROUND

1. Field of the Disclosure

The present disclosure generally relates to digital integrated circuits including memory areas to be operated in a low power regime, such as integrated circuits comprising real time functionality.

2. Description of the Related Art

In manufacturing semiconductor devices including a relatively complex circuitry, the design and verification, i.e., the testing and simulation, of the device may represent a part of the manufacturing process, which is frequently underestimated in terms of cost and effort required to obtain reliable data with respect to proper functionality and reliability of the device. One reason in failing to meet performance specifications of the integrated circuit may reside in design errors that may be identified and remedied by circuit verification on the basis of software simulation and/or prototype testing prior to mass production of the integrated circuits under consideration. An improper functionality of the integrated circuit may further be caused by the manufacturing process itself, when the completed circuitry does not correspond to the verified circuit design, owing to process fluctuations in one or more of the large number of process steps involved. Although measurement and test procedures are incorporated at many points in the manufacturing process, it is nevertheless extremely important to ascertain the correct functioning of the final semiconductor device, since, according to a common rule of thumb, the costs caused by defective chips increase with each assembly phase by approximately one order of magnitude. For example, the costs caused by a defective circuit board including a faulty chip are typically significantly higher than identifying a defective chip prior to shipping and assembling the circuit board. The same holds true for a system, when a failure thereof is caused by one or more defective circuit boards, as downtime of an industrial system may result in averaged costs of approximately several hundred dollars per minute compared to a price of a few dollars for an integrated circuit chip having caused the defect.

Hence, there is a vital interest in developing efficient design strategies and test and verification procedures to accelerate the design phase while not unduly contributing to circuit failures caused by design flaws. In particular, with the demand for more features and lower costs of circuits, there is a tendency to integrate a plurality of different circuit portions into a single chip to provide a complete system on a chip (SOC). A semiconductor device comprising various functional blocks may typically include, in addition to one or more logic blocks, one or more embedded memory portions, such as are used as on-chip cache for CPUs or as buffers for data packets that are transferred between different clock domains.

However, the increasing complexity of advanced digital circuits is typically associated with an increase of power consumption, since, in digital circuitry, the power consumption may increase with increasing clock frequency and the number of active components, that is, of transistors used for forming the basic digital circuit components, such as inverters, latches, flip flops and the like. For example, a complex microprocessor including hundreds of millions of transistor elements and operating at a clock frequency of several hundred MHz or even higher may consume 50-100 watts, which may impose significant constraints on the heat dissipation requirements with respect to the package of the device. In other cases, portable electronic devices including complex control circuitry on the basis of digital functional blocks have experienced a widespread usage in many technical fields, wherein one aspect of the economic success is the usable operating time on the basis of the power source used in these devices. Consequently, great efforts are being made in an attempt to reduce power consumption for a given degree of complexity of a digital circuit block. In a complex digital circuit, typically two types of circuit design, i.e., synchronous and asynchronous designs, may be used. In a synchronous design, the entire circuit may be operated on the basis of a system clock, which is connected to all clock operated digital gates. On the other hand, in an asynchronous design, the circuit, or at least portions thereof, may be operated without a clock signal so that switching events may occur only when an input of a specific functional element may change. Although, in principle, an asynchronous design may have the potential for reducing power consumption, other issues associated with asynchronous designs may render this concept less attractive for complex circuitry, since the effort for design and verification of asynchronous circuit portions may be significantly higher compared to a clock-based design operating on the basis of a system clock signal. That is, for synchronous digital designs, automated synthesis rules, for instance in the form of CAD (computer aided design) tools, may be used for generating a specified circuit design, wherein well-defined timing constraints may be taken into consideration. For example, the entire distribution of the clock signals within the synchronous digital circuit may be based on a desired timing, thereby enabling the creation of a respective clock tree to provide the clock signal with a specified minimum delay to any circuit portions of the digital design. Consequently, designing and verification of the circuit may be based on well-established static analysis techniques, thereby significantly reducing the overall time for designing and manufacturing complex digital integrated circuits, as previously explained. Moreover, the basic design of a synchronous digital circuit may be used for different technology standards without changes, since the functionality may be maintained as long as respective manufacturing-related constraints are respected, i.e., as long as the clock signal delays are within the tolerances set by the technology standard under consideration.

On the other hand, digital circuitry including significant portions with asynchronous design may per se have significantly reduced power consumption but may require significant efforts for designing and in particular for verifying the asynchronous circuit design. That is, during the test procedure a dynamic simulation of the circuitry may have to be performed, thereby significantly contributing to the overall manufacturing time, in particular when highly complex circuits are considered. Moreover, the circuit design may not be readily ported to a different technology standard, since the “response” of the digital circuit may involve a highly dynamic behavior, which may significantly depend on the manufacturing technology under consideration, therefore requiring significant re-design or even a new design of the circuit under consideration.

Since typically the benefits of synchronous design, such as reduced design and verification efforts for complex circuits, may represent essential aspects for manufacturing of semiconductor devices, a plurality of techniques have been developed to also reduce power consumption in synchronous digital circuits. In addition to maintaining a low operating voltage, other concepts may also be used in which currently non-used circuit portions may be disabled by switching off the clock signal for these circuit portions. A corresponding technique for temporarily disabling the clock signal may be referred to as clock gating. During the clock gating, a control signal, which may be generated on the basis of the knowledge that specific logic elements may not be required to be active, is used as a “gate” for the clock signal that is applied to the logic circuit portion under consideration. The additional amount of circuitry required for realizing appropriate clock gating mechanisms may outweigh the benefits with respect to power consumption, while also providing the possibility of using a fully synchronous circuit design having the above-identified benefits.

As previously explained, extended circuit functionality may be increasingly incorporated in a plurality of electronic devices that may have to be operated on the basis of portable power sources, while a certain basic functionality may even be maintained in a substantially deactivated state of the electronic device. One important functionality in this respect is maintaining and monitoring the time and date to enable time-controlled events, such as activation of the entire system or parts thereof or time-controlled operation of the system upon re-activation of the circuit. For this purpose, so-called real time clocks have been developed in which the current time may be monitored in a human perceivable manner, that is, the time is actually monitored and maintained in the form of seconds, minutes, hours, days, weeks, months, years and the like, depending on the desired capacity of the real time clock. Thus, for power critical applications, the power consumption of the real time clock, if represented as an internal part of the overall digital circuit, is to be designed and operated such that power consumption is as low as possible since the real time clock unit is active when the remaining portion of the circuit is de-activated. Consequently, the capability of tracking the time may depend on the overall power consumption of the real time clock and the capacity of a respective power source, which may frequently be provided in the form of a back-up capacitor, a rechargeable battery and the like. A real time clock typically comprises a memory area including a specified number of storage cells so as to be able to store the respective real time values in an appropriate format, while also appropriate time counters and additional circuitry may be provided for updating the real time values in the storage cells on a regular basis.

FIG. 1 schematically illustrates a block diagram of a basic configuration of a real time clock unit, which is designed for low power consumption. In FIG. 1, a real time clock unit 100 comprises a memory area 110 including a respective number of storage cells, such as registers and the like, designed to maintain real time values in the form of seconds, minutes, hours and the like, depending on the desired time resolution and time horizon for the time monitoring capability of the unit 100. Furthermore, a clock update unit 120 may have incorporated therein respective time counters to generate the desired real time values on the basis of a clock signal “clk.” The clock update unit 120 may also comprise appropriate circuits, for instance comparators and the like, in order to detect pre-programmed events and to provide respective alarm signals, depending on the overall programming of the unit 100. The unit 120 may communicate with the memory area 110 via a bus interface 130, thereby enabling data and control signal exchange between the components of the unit 100. Furthermore, an interface 140 may be provided to enable communication with other circuit portions, access of the unit 100 by external components and the like. It should be appreciated that when the real time unit 100 may represent a stand-alone configuration, the clock signal “clk” may be generated internally on the basis of appropriately designed oscillators in combination with divider circuits and the like. As previously explained, in view of low power consumption, the overall design of the unit 100 may be provided as an asynchronous design, for example a latch-based design, so that respective circuit portions of the unit 100 may be activated “on demand.” wherein, in particular in the storage memory 110, only parts are activated that are actually accessed by the clock updating unit 120. Consequently, minimal power consumption may be achieved during operation of the unit 100, in which the clock updating unit 120 may provide updated real time values, which may then be stored in respective storage cells of the memory area 110.

As discussed above, however, in particular when the unit 100 represents a portion of a complex digital circuit, the design of the overall circuit may require increased implementation efforts and may not readily allow transfer of the circuit design under consideration to other chip technologies due to the usage of a technology dependent design.

The present disclosure is directed to various methods and devices that may avoid, or at least reduce, the effects of one or more of the problems identified above.

### SUMMARY OF THE DISCLOSURE

The following presents a simplified summary of the disclosure in order to provide a basic understanding of some aspects disclosed herein. This summary is not an exhaustive overview, and it is not intended to identify key or critical elements of the invention or to delineate the scope of the invention. Its sole purpose is to present some concepts in a simplified form as a prelude to the more detailed description that is discussed later.

Generally, the principles disclosed herein relate to techniques in which a memory area of a digital circuit may be divided into “frequency groups,” wherein each frequency group may correspond to a group of storage cells that may have to be commonly accessed in a highly predictable manner during operation of the device. In this way, the memory area may be provided as a synchronous design, wherein each frequency group is associated with an appropriate gate clocking mechanism so that the memory area may be accessed by merely activating one or more specific frequency groups without activating the entire memory area, which otherwise would result in undue power consumption. Hence, a fully synchronous design may be used while nevertheless maintaining power consumption during accessing of the memory area at a low level. In one illustrative aspect disclosed herein, a real time clock unit may be provided in a synchronous design, wherein the memory area may be divided into respective frequency groups, since the storage cells may have to be accessed in a predictable manner without affecting the overall operation of the real time clock. Consequently, well-established automated synthesis and verification procedures may be used, while nevertheless providing a circuit design resulting in a low power consumption.

One illustrative integrated circuit disclosed herein comprises a clock source configured to provide a clock signal. Furthermore, a plurality of clock gating units are provided, each of which is connected to receive the clock signal and a control signal, wherein the plurality of clock gating units are configured to provide the clock signal when the control signal is in an asserted state. The integrated circuit further comprises a memory area comprising storage cells divided into a plurality of frequency groups, wherein each frequency group of storage cells has a predetermined different access frequency during a specified operating mode and receives the clock signal from a respective one of the plurality of clock gating units.

One illustrative real time clock unit disclosed herein comprises a plurality of synchronously designed storage cells that are divided into different frequency groups. Furthermore, the real time clock unit comprises a clock update unit connected to the plurality of storage cells. Furthermore, a plurality of clock gating units is provided, each of which is associated with a respective one of the different frequency groups.

One illustrative method disclosed herein relates to forming a semiconductor device. The method comprises determining a first frequency for accessing a first group of storage cells of the semiconductor device during a specified operating mode. The method further comprises determining a second frequency for accessing a second group of storage cells in the specified operating mode. Furthermore, the semiconductor device is designed on the basis of a synchronous design by providing a first clock gating mechanism associated with the first group of storage cells and a second clock gating mechanism for the second group of storage cells. Finally, the method comprises manufacturing the semiconductor device using the synchronous design.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically illustrates a circuit diagram of a conventional low power real time clock unit;

FIG. 2a schematically illustrates a circuit diagram of a synchronous digital circuit including a memory area with a plurality of frequency groups connected to associated gate blocking units, according to illustrative embodiments;

FIG. 2b schematically illustrates a circuit diagram of an integrated circuit including a real time clock unit formed on the basis of a synchronous design with a plurality of clock gating units connected to a plurality of groups of storage cells having identical access frequency, according to illustrative embodiments; and

FIG. 3 schematically illustrates a flow diagram of a method for forming a semiconductor device on the basis of a synchronous design including a memory area, such as the memory of a real time clock, connected to a plurality of clock gating units, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter disclosed herein relates to methods and integrated circuits that may be formed on the basis of a synchronous design, thereby enhancing the design and the verification of the devices, while also providing portability to a desired chip technology. In some illustrative aspects disclosed herein, a low power operating mode may be achieved for circuit portions including a memory area, wherein the individual storage cells of the memory area are classified into respective frequency groups, wherein a frequency group is to be understood as a group in which the storage cells may have the same frequency of being accessed during the low power operation mode. That is, in many applications, the frequency of accessing specified memory portions may be predictable due to the nature of the functionality of the circuit portion under consideration. For example, if values of a predetermined format may have to be stored or retrieved on a regular basis, the corresponding storage cells may be decoupled from an overall system clock during any time intervals between the regularly occurring access times. Hence, memory portions not required during accessing a specific group of storage cells may remain de-activated, thereby avoiding the supply of the clock signal to the entire memory area, which may otherwise consume undue power. Thus, if a plurality of different values, which may have different formats, may have to be stored in or retrieved from a memory area, appropriately selected storage cells of the memory area may be combined to define a frequency group, each of which may have a different access frequency. Consequently, the memory area may be formed in accordance with a synchronous design on the basis of a system clock, while respective clock gating mechanisms may provide the system clock signal separately to the individual frequency groups since typically only this single frequency group may be required for performing the pending memory operation.

In one illustrative aspect, the synchronously designed memory area may represent the memory of a real time clock unit, in which access events and the format of the values to be stored in the memory area are predictable due to the nature of the operational behavior of the real time clock unit. For example, a clock updating unit, i.e., a respective assembly of counters and other circuitry, may provide real time values, for instance in the form of seconds, minutes and the like, according to a desired time resolution of the real time clock unit. Since the format of the respective real time values is predetermined and also the real time values have to be stored on a regular basis, however at a different frequency, the storage cells may be correspondingly grouped so that any storage cell associated with, for example, the real time values for seconds may be connected to a clock gating mechanism, while other storage cells associated with other real time values, such as minutes, may also be connected to a clock gating unit, thereby restricting the supply of the system clock signal to the memory area such that only those storage cells may be activated that may actually be accessed during the memory operation under consideration. As a consequence, the overall power consumption of the memory area may be comparable or even less compared to an asynchronous memory design, while implementation effort is significantly less compared to, for instance, a latch-based design, as may typically be used for real time clock units to be operated in a low power mode. Furthermore, the overall circuit design may be verified by a formal static timing analysis and, during the automated synthesis, one common design constraint may be used for the entire clock tree of the digital circuit.

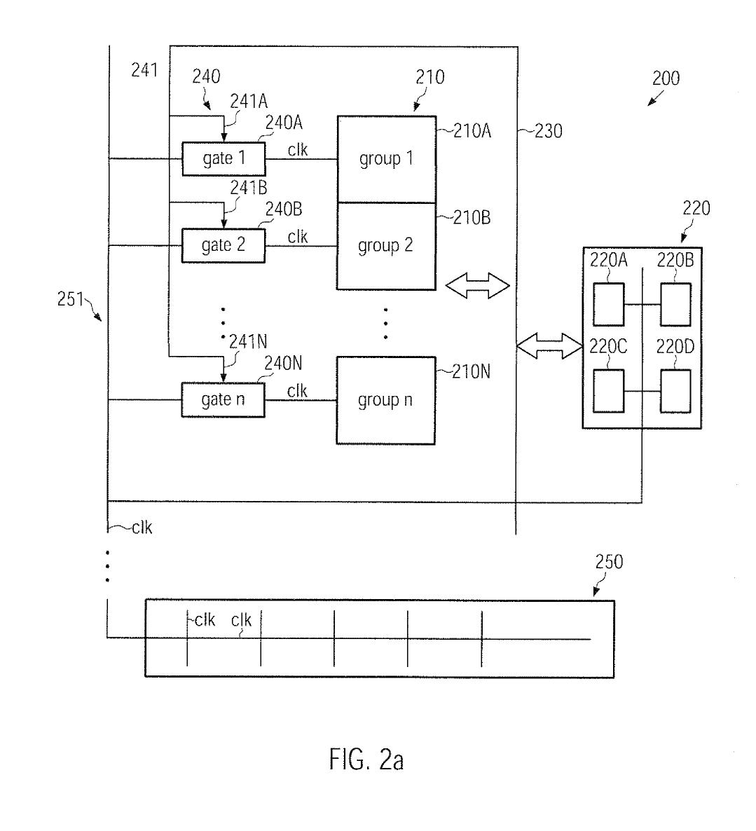

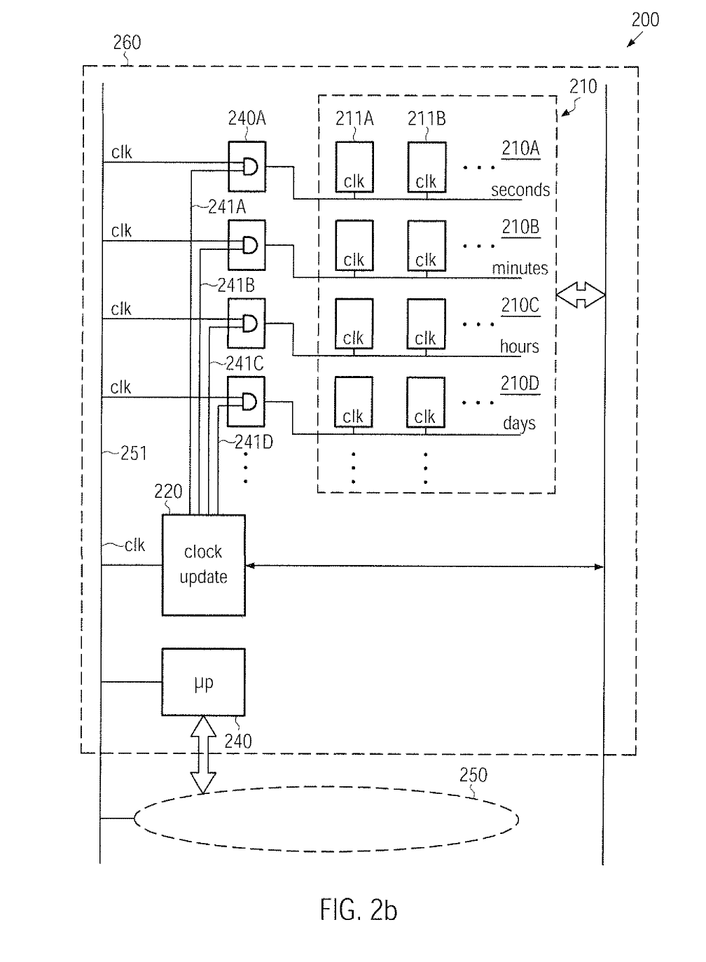

FIG. 2a schematically illustrates a synchronously designed integrated circuit 200 according to illustrative embodiments. The circuit 200 may thus comprise a “clock tree” 251, which may provide a clock signal from a system clock source (not shown) to each of the clock-based digital components of the circuit 200. That is, the circuit 200 is operated on the basis of a clock signal “clk” provided via the clock tree 251, wherein the clock tree may be designed in accordance with well-established concepts so as to be compatible with the manufacturing technology under consideration. The clock tree 251 may typically be designed such that a maximum clock signal delay or skew may be within predefined tolerances, which may be determined on the basis of the process technology and the respective manufacturing variations under consideration. Furthermore, the circuit 200 may comprise a plurality of functional units that are appropriately connected to the clock tree 251. In the embodiment shown, a memory area 210 may be provided and may include a plurality of storage cells (not shown) which are also provided in the form of synchronously designed storage cells, thereby requiring the application of the system clock “clk.” The memory area 210 may represent a memory, in which access events for certain portions may be predictable, for instance due to the operational behavior of the integrated circuit 200, as previously explained. Therefore, storage cells having the same predictable access frequency may be combined to a specific frequency group, such as the groups 210A, 210B, 210N. Furthermore, each of the groups 210A, 210B, 210N may be connected to a respective one of a plurality of clock gating units 240. Thus, a respective one of the clock gating units 240A, 240B, 240N may be connected with a dedicated group 210A, 210B, 210N. Each of the clock gating units 240 may be configured to receive the system clock signal “clk” and provide the signal “clk” to its associated group upon receiving an asserted control signal 241. That is, the control signal 241 may include individual control signal portions 241A, 241B, 241N so as to selectively activate the clock gating units 240A, 240B, 240N. Basically, each of the clock gating units 240 may represent a logic “AND” function combining the system clock “clk” and the control signal 241.

The control signal 241 may be provided via an interface 230 from an update unit 220, which may comprise a plurality of functional units 220A, 220B, 220C, 220D, which may be connected to the clock tree 251 so as to realize a synchronous operation, as previously explained. Furthermore, the circuit 200 may comprise a functional block 250, which may include complex digital circuitry and the like, which may be connected to the clock tree 251 according to well-established design principles, wherein, for convenience, respective functional units of the block 250 are not illustrated in FIG. 2a. It should be appreciated that the integrated circuit 200 may represent a design state of the circuit 200, while, in other cases, the various components thereof may be implemented into a semiconductor chip in accordance with a specified manufacturing technology.

During operation of the circuit 200, irrespective of whether it is in a design state or represents an actual hardware configuration, the clock tree 251 may supply the clock signal “clk” for operating the functional block 250 and the update unit 220. For example, the update unit 220 may create memory requests for the various groups 210A, 210B, 210N with different frequency, for instance, if data have to be stored or retrieved on a regular basis, wherein respective access time intervals are different for the groups 210A, 210B, 210N. Consequently, upon performing a memory operation, the update unit 220 may assert a specific one of the control signals 241A, 241B, 241N, thereby activating the respective group 210A, 210B, 210N which has to be accessed by the pending memory operation. Consequently, during this operational mode, that is, an operating mode resulting in a regular access of the memory portion 210, a significant power saving may be accomplished, since the groups 210A, 210B, 210N may be accessed individually, while maintaining the remaining groups in a de-activated state. For example, in a low power operating mode, in which the functional block 250 may be substantially de-activated, the power consumption of the circuit 200 may be substantially determined by the operation of the update unit 220 and the clock tree 251, while also the memory portion 210 may not essentially contribute to the overall power consumption, since only dedicated groups 210A, 210B, 210N may be activated at a time.

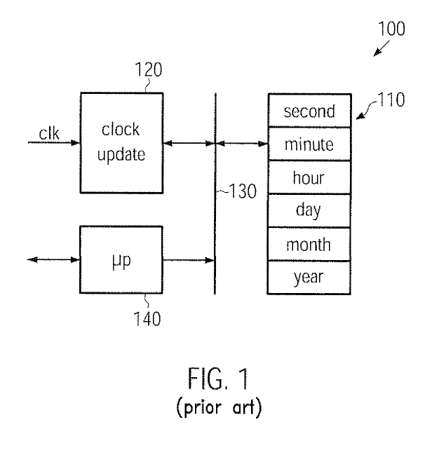

FIG. 2b schematically illustrates the synchronous integrated circuit 200 according to a further illustrative embodiment, in which the circuit 200 comprises a real time clock unit 260. In this case, the memory area 210 may comprise a plurality of storage cells 211A, 211B combined to the groups 210A, 210B, 210C, 210D such that the storage cells 211 of one group may correspond to a real time value as required for monitoring the current time and date. For example, the frequency group 210A may correspond to storage cells which are associated with real time values indicating the number of seconds of the current time. Similarly, the group 210B may correspond to the current value of the number of minutes, while the groups 210C, 210D may represent those storage cells associated with storing real time values for hours and days, respectively. Depending on the desired time resolution of the real time clock unit 260, further groups 210 may correspond to weeks, months, years, fractions of seconds and the like. Hence, each of the groups 210A, 210B, 210C, 210D may at least comprise a sufficient number of storage cells 211 so as to allow storage of the real time value in a required format. It should be appreciated, however, that the memory area 210 may comprise additional storage cells for storing additional data, wherein some of these additional storage cells may also have a predictable access behavior and may therefore be assigned to an appropriate group 210. Any other storage cells having a non-predictable access behavior may also be connected to the clock tree 251 without the intermediate clock gating units 240A, 240B, 240C, 240D. Moreover, the updating unit 220, now referred to as clock updating unit, may be configured to provide the plurality of control signals 241A, 241B, 241C, 241D so as to selectively supply the system clock “clk” to one or more of the groups 210, as previously explained. Furthermore, the clock updating unit 220 may further comprise any further circuitry for performing desired real time clock functions, such as generating alarm signals and the like. It should be appreciated that, in some illustrative embodiments, the real time clock unit 260 may be provided as a stand-alone unit, while, in other cases, the unit 260 may be one part of the circuit 200, which may additionally comprise other functional blocks, such as the block 250. In this case, the real time clock unit 260, in combination with the block 250, may be provided for enhanced design and verification efficiency due to the synchronous design, while also allowing a low power mode, since the memory area 210, although provided as a synchronous design, may be activated on demand, wherein only storage cells are connected to the system clock which are actually accessed by the clock updating unit 220. Hence a comparable or even enhanced behavior with respect to power consumption relative to an asynchronous design, as previously explained with reference to FIG. 1, may be achieved. Therefore, the real time clock unit 260 may be operated on the basis of low power requirements, which may be important for portable devices, in which, during operation and also during substantially inactive states, in which most parts of the overall circuit 200 may be de-activated except for the real time clock unit 260, a reduced power consumption may significantly extend usability of the integrated circuit 200.

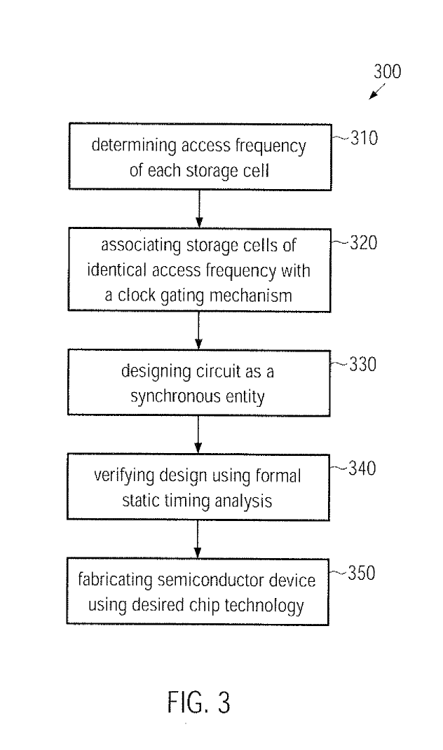

With reference to FIG. 3, a typical process flow for manufacturing the integrated circuit 200, which may include the design and verification phase, will be described. The overall manufacturing process 300 may begin in block 310, in which the access frequency of the plurality of storage cells may be determined for a given functional behavior of a synchronously designed integrated circuit under consideration. In this context, the access frequency is to be understood not only as the frequency of performing memory operations on a specified storage cell, but also the “point in time” of the access, meaning that members of the same frequency group will be accessed commonly, that is within a predefined number of clock cycles of the system clock “clk.” That is, in this step, it may be decided which storage cells may always be accessed with a specified number of clock cycles, wherein the temporal distance in form of the number of clock cycles to an “adjacent” frequency group, i.e., a group that is accessed more frequently or less frequently, is typically significantly greater than the temporal “span” of the frequency group under consideration, so that a large number of clock cycles may be “saved” by separately activating the individual groups. For example, for real time clock applications, the number of storage cells, i.e., the data format, as well as performing memory operations, are highly predictable, since the various real time values may have to be stored on a regular basis, wherein the storage cells representing “seconds” may be accessed within a specified number of clock cycles, while events for accessing the group representing “minutes” may be “separated” by a very large number of clock cycles, except for the “rare” cases when the “seconds” group and the “minutes” group both have to be updated.

After identifying respective storage cells having the same predicted access frequency, in step 320, storage cells of identical access frequency may be combined to a group and may be associated with a dedicated clock gating mechanism. Based on the knowledge of the number and the members of the respective frequency groups and the number of required clock gating mechanisms, the synchronous circuit may be designed, for instance by taking into consideration other functionalities that may not be directly associated with the memory area under consideration and the corresponding circuitry associated therewith. After establishing the design of the circuit, which may be achieved on the basis of well-established automatic synthesis procedures using automatic synthesis tools, as are well known in the art, in step 340, the resulting circuit design may be verified, wherein, according to the synchronous design, formal static timing analysis procedures may be used. Consequently, since the memory area under consideration, which may represent a portion of a real time clock unit, as previously explained, may be provided with a synchronous design, the steps 330 and 340 may be performed with high efficiency compared to circuit designs including asynchronous circuit portions. After verification of the overall design, the integrated circuit may actually be implemented into a hardware configuration, which may be accomplished by providing one or more prototypes and thereafter using the design to fabricate semiconductor devices during volume production according to step 350. In this step, an appropriate chip technology may be used. That is, respective manufacturing processes may be performed to produce individual transistors, capacitors and the like, according to the established synchronous circuit design, wherein the individual semiconductor devices may have predetermined critical device dimensions, such as the gate length of field effect transistors, thereby requiring appropriately adapted manufacturing processes, for instance, photolithography steps, deposition steps, ion implantation steps, etch steps and the like. As previously explained, the actual hardware implementation of the synchronous design may depend on the available chip technology, wherein, however, the basic circuit design may be used for any appropriate chip technology, as long as the constraints with respect to the clock tree are compatible with manufacturing specific characteristics of the chip technology under consideration.

As a result, the subject matter disclosed herein provides techniques and integrated circuits formed on the basis of a synchronous design, wherein, in illustrative embodiments, a real time clock unit may be formed so as to exhibit low power consumption by operating a respective memory area by using clock gating techniques. That is, since access of storage cells in the memory area is predictable, storage cells of identical access behavior may be combined, thereby avoiding the activation of all storage cells when performing a memory operation for reading or writing data. Consequently, low power consumption may be achieved, while significant advantages with respect to design and verification may be accomplished compared to asynchronous designs.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. An integrated circuit comprising:
a clock source configured to provide a clock signal;
a plurality of clock gating units, each of which is connected to receive said clock signal and a control signal, said plurality of clock gating units being configured to provide said clock signal when said control signal is in an asserted state; and
a memory area comprising storage cells divided into a plurality of frequency groups, each frequency group of storage cells having a predetermined different access frequency during a specified operating mode and receiving said clock signal from a respective one of said plurality of clock gating units.

2. The integrated circuit of claim 1, further comprising a clock update circuit operatively connected to said memory area and configured to generate real time values and to update said plurality of storage cells with said real time values.

3. The integrated circuit of claim 2, wherein said predetermined access frequencies correspond to update intervals for said real time values.

4. The integrated circuit of claim 3, further comprising a functional block connected to receive said clock signal and an interface configured to enable access to said memory area by said functional block.

5. The integrated circuit of claim 4, wherein said functional block is configured to instruct assertion of said control signal to activate at least one of said plurality of groups prior to accessing said memory area.

6. The integrated circuit of claim 5, wherein assertion of said control signal activates each of said storage cells.

7. The integrated circuit of claim 2, wherein said storage cells comprise at least storage space for real time values corresponding to a current time and a current date.

8. A real time clock unit, comprising
a plurality of synchronously designed storage cells, said plurality of storage cells being divided into different frequency groups;
a clock update unit connected to said plurality of storage cells; and
a plurality of clock gating units, each of which is associated with a respective one of said different frequency groups.

9. The real time clock unit of claim 8, wherein each of said clock gating units is configured to activate an associated frequency group upon receipt of an asserted control signal.

10. The real time clock unit of claim 9, wherein said clock update unit is configured to commonly assert said control signal for each of said clock gating units.

11. The real time clock unit of claim 10, wherein said clock update unit is further configured to receive an enable signal for enabling access to at least some of said different frequency groups by an external unit.

12. The real time clock unit of claim 8, further comprising a semiconductor substrate including a semiconductor layer formed in and above said plurality of storage cells.

13. The real time clock unit of claim 12, further comprising a functional logic block formed in and above said semiconductor layer.

14. The real time clock unit of claim 13, wherein said functional logic block is configured to cause assertion of said control signal.

15. The real time clock unit of claim 8, wherein each of said frequency groups is grouped according to an access frequency of members of the groups during a specified operating mode.

16. A method for forming a semiconductor device, the method comprising:
determining a first frequency for accessing a first group of storage cells of said semiconductor device during a specified operating mode;
determining a second frequency for accessing a second group of storage cells in said specified operating mode;
designing said semiconductor device on the basis of a synchronous design by providing a first clock gating mechanism associated with said first group of storage cells and a second clock gating mechanism for said second group of storage cells; and
manufacturing said semiconductor device using said synchronous design.

17. The method of claim 16, wherein said first and second groups of storage cells correspond to storage cells for storing real time values.

18. The method of claim 17, further comprising designing a clock update unit on the basis of said synchronous design.

19. The method of claim 18, further comprising designing at least one functional logic block on the basis of said synchronous design, wherein said at least one functional block is configured to access said first and second groups of storage cells.

20. The method of claim 16, wherein at least some further groups of storage cells are provided that have a different frequency for being accessed during said specified operating mode and wherein each of said at least some further groups of storage cells is associated with a dedicated clock gating mechanism.
